(19) United States
(12) Patent Application Publication
(10) Pub. No.: US 2017/0245383 A1
(43) Pub. Date: Aug. 24, 2017

(54) Fall-Proof Method Using Terminal Device Accessory, Terminal Device Accessory and Terminal Device

(71) Applicant: ZTE CORPORATION, Shenzhen City, Guangdong Province (CN)

(72) Inventor: Dejuan FENG, Shenzhen (CN)

(21) Appl. No.: 15/503,405

(22) PCT Filed: Oct. 15, 2014
(86) PCT No.: PCT/CN2014/088662

§ 371 Date: Feb. 13, 2017

(30) Foreign Application Priority Data
Aug. 13, 2014 (CN) 201410397680.5

(51) Int. Cl. H05K 5/02; H01R 24/58; G06F 1/16

(52) U.S. Cl. CPC H05K 5/0217; H05K 5/0247; G06F 1/1656; H01R 24/58; H01R 2103/00

(57) ABSTRACT

A fall-proof method using a terminal device accessory, a terminal device accessory and a terminal device are provided. The terminal device accessory includes: an accessory body, a control module at one end of the accessory body, a popup component on the accessory body and an accessory exposed part at the other end of the accessory body, herein the accessory exposed part is capable of being unfolded in an umbrella shape. The fall-proof method using the terminal device accessory includes: when the terminal device is in a weightless state, the control module on the accessory body inserted into the earphone jack of the terminal device receiving a fall-proof instruction sent by the terminal device; and the control module triggering the popup component to extend in a direction towards the outside of the earphone jack according to the fall-proof instruction and jack up an accessory exposed part.

### TECHNICAL FIELD

The present document relates to the field of terminal device protection, in particular to a fall-proof method using a terminal device accessory, a terminal device accessory and a terminal device.

### BACKGROUND

At present, some terminal devices, especially terminal devices with earphone jacks such as mobile phones, tablet computers, portable game machines and music play terminals have already been an indispensable part of people's life. However, when terminal devices are used, terminal devices easily fall down due to negligence and carelessness. Even though terminal devices are put in clothes pockets, when some exercises are done, terminal devices easily slip off from pockets and fall down. If a terminal device falls down, the terminal device is easily damaged. Under unserious situations, bruise and depression are caused and influence the appearance; and under serious situations, the terminal device cannot be used any longer and great inconvenience is caused to life.

By taking smart phones as an example, screens of the existing smart phones become larger and larger, and consequently the screens are more easily damaged if the smart phones fall down during use. If the fragile screens are damaged, the maintenance cost is very high.

Therefore, it is necessary to provide an effective method to protect a terminal device when the terminal device falls down, so as to reduce the loss caused for a reason that the terminal device falls down.

### SUMMARY

In order to solve the problem, the embodiments of the present document provide a fall-proof method using a terminal device accessory, a terminal device accessory and a terminal device, which can effectively prevent the appearance and certain functions of the terminal device from being damaged when the terminal device falls down.

According to one embodiment of the present document, the present document provides a fall-proof method using a terminal device accessory, the terminal device accessory including: an accessory body, a control module at one end of the accessory body, a popup component on the accessory body and an accessory exposed part at the other end of the accessory body and arranged to be fit with a side surface of a terminal device when the accessory body is inserted into an earphone jack, the accessory exposed part being capable of being unfolded in an umbrella shape; the method including:

when the terminal device is in a weightless state, the control module on the accessory body inserted into the earphone jack of the terminal device receiving a fall-proof instruction sent by the terminal device; and

the control module triggering the popup component to extend towards the outside of the earphone jack and jack up the accessory exposed part according to the fall-proof instruction such that the accessory exposed part is automatically unfolded in the umbrella shape.

Alternatively, the control module on the accessory body inserted into the earphone jack of the terminal device receiving the fall-proof instruction sent by the terminal device includes:

the control module on the accessory body inserted into the earphone jack of the terminal device receiving the fall-proof instruction sent by the terminal device through a left sound channel contact end, a right sound channel contact end or a microphone contact end of the earphone jack.

Alternatively, the terminal device accessory further includes: an airbag in the accessory exposed part and the method further includes:

when the popup component jacks up the accessory exposed part, the control module triggering the airbag to pop up from the inside of the accessory exposed part and be unfolded.

According to another embodiment of the present document, the present document provides a terminal device accessory for being inserted into an earphone jack of a terminal device, including:

an accessory body;

a control module at one end of the accessory body, arranged to, when the terminal device is in a weightless state, receive a fall-proof instruction sent by the terminal and generate and output a trigger signal according to the fall-proof instruction;

an accessory exposed part at the other end of the accessory body, arranged to be fit with a side surface of the terminal device when the accessory body is inserted into the earphone jack, the accessory exposed part being capable of being unfolded in an umbrella shape; and

a popup component on the accessory body, arranged to extend towards the outside of the earphone jack and jack up the accessory exposed part according to the trigger signal output by the control module such that the accessory exposed part is automatically unfolded in the umbrella shape, a signal input end of the popup component being connected with a signal output end of the control module.

Alternatively, the control module includes: a control circuit, a signal input end connected with the control circuit and a signal output end connected with the control circuit, herein the signal input end is connected with a left sound channel contact end, a right sound channel contact end or a microphone contact end in the earphone jack.

Alternatively, the accessory body includes: a first columnar body and a second columnar body, one end of the first columnar body is connected with one end of the popup component, the other end of the popup component is connected with one end of the second columnar body and the other end of the second columnar body is connected with the accessory exposed part, herein the control module is located on the first columnar body.

Alternatively, the other end of the second columnar body is connected with the accessory exposed part in a fixed or rotatable manner.

Alternatively, the terminal device accessory further includes: an airbag in the accessory exposed part, which is arranged to, when the popup component jacks up the accessory exposed part, pop up from the inside of the accessory exposed part and be unfolded.

Alternatively, the other end of the second columnar body is connected with the accessory exposed part in a fixed or rotatable manner.

According to another embodiment of the present document, the present document provides a terminal device accessory, including:

an accessory exposed part, the accessory exposed part being capable of being unfolded in an umbrella shape; and

an insertion part connected with the accessory exposed part and arranged to be fixed in an earphone jack of a terminal device, a popup component being arranged on the insertion part, the popup component being capable of jacking up the accessory exposed part such that the accessory exposed part is automatically unfolded in the umbrella shape.

Alternatively, the insertion part includes: a first columnar body and a second columnar body, one end of the first columnar body is connected with one end of the popup component, the other end of the popup component is connected with one end of the second columnar body and the other end of the second columnar body is connected with the accessory exposed part.

Alternatively, the other end of the second columnar body is connected with the accessory exposed part in a fixed or rotatable manner.

Alternatively, the terminal device accessory further includes: an airbag in the accessory exposed part, and the airbag is automatically unfolded when the accessory exposed part is jacked up.

Alternatively, the other end of the second columnar body is connected with the accessory exposed part in a fixed or rotatable manner.

According to another embodiment of the present document, the present document provides a terminal device, including: a terminal device accessory, the terminal device accessory including:

an accessory body;

a control module at one end of the accessory body, arranged to, when the terminal device is in a weightless state, receive a fall-proof instruction sent by the terminal device and generate and output a trigger signal according to the fall-proof instruction;

an accessory exposed part at the other end of the accessory body, arranged to be fit with a side surface of the terminal device when the accessory body is inserted into an earphone jack, the accessory exposed part being capable of being unfolded in an umbrella shape; and

a popup component on the accessory body, arranged to extend towards the outside of the earphone jack and jack up the accessory exposed part according to the trigger signal output by the control module such that the accessory exposed part is automatically unfolded in the umbrella shape, a signal input end of the popup component being connected with a signal output end of the control module.

According to another embodiment of the present document, the present document provides a terminal device, including a terminal device accessory, the terminal device accessory including:

an accessory exposed part, the accessory exposed part being capable of being unfolded in an umbrella shape; and

an insertion part connected with the accessory exposed part and arranged to be fixed in an earphone jack of a terminal device, a popup component being arranged on the insertion part, the popup component being capable of jacking up the accessory exposed part such that the accessory exposed part is automatically unfolded in the umbrella shape.

By adopting the fall-proof method using the terminal device accessory, the terminal device accessory and the terminal device provided by the embodiments of the present document, the terminal device accessory is inserted into the earphone jack of the terminal device, the terminal device can send the fall-proof instruction to the control module of the terminal device accessory when the terminal device is in the weightless state, the control module can trigger the popup component to extend towards the outside of the earphone jack along the axial direction of the accessory body and jack up the accessory exposed part after receiving the fall-proof instruction, and since the jacked-up accessory exposed part can increase certain air resistance, the falling speed of the terminal device is reduced to prevent the terminal device from being damaged. In addition, if the earphone jack faces to the ground when the terminal device falls down, the accessory exposed part can prevent the terminal device from directly contacting the ground to achieve an air cushion effect, and the popup component itself has elasticity and will further relieve the impact force to the terminal device when the terminal device falls down.

Since the accessory exposed part will be unfolded in the umbrella shape when it is jacked up, if the earphone jack faces to a direction of sky when the terminal device falls down, the accessory exposed part can achieve an effect similar to a parachute; and if other side surfaces of the terminal device face to the ground when the terminal device falls down, the accessory exposed part can firstly contact the ground due to large unfolded area to change a falling direction and relieve the impact force.

After the exposed part of the terminal device is jacked up, the airbag can pop up and be unfolded. Thus, if the earphone jack faces to the direction of sky when the terminal device falls down, the airbag which pops up can also achieve an effect of reducing speed; if the earphone jack faces to the ground when the terminal device falls down, the airbag can further prevent the terminal device from directly contacting the ground to achieve an effect similar to an air cushion; and if other side surfaces of the terminal device face to the ground when the terminal device falls down, the airbag will contact the ground prior to the terminal device due to the large volume of the airbag, thereby the impact force when the terminal device falls down is reduced and the terminal device is prevented from being damaged.

### BRIEF DESCRIPTION OF DRAWINGS

FIG. 1 illustrates a flowchart of a fall-proof method using a terminal device accessory in the embodiment of the present document.

FIG. 2 illustrates a structural schematic view of a terminal device accessory mounted on a terminal device in the embodiment of the present document.

FIG. 3 illustrates a top view of an accessory exposed part in the embodiment of the present document.

FIG. 4 illustrates a side view of an accessory body in the embodiment of the present document.

FIG. 5 illustrates a state schematic view of a terminal device accessory when a terminal device falls down provided by the embodiment of the present document.

FIG. 6 illustrates an internal structural block diagram of a terminal device accessory provided by the embodiment of the present document.

In the drawings: 1—accessory body; 2—control module; 3—popup component; 4—accessory exposed part; 5—earphone jack; 6—airbag; 101—first columnar body; 102—second columnar body; 7—terminal device.

### DETAILED DESCRIPTION

The specific embodiments of the present document will be described below in detail with reference to the accompanying drawings. The embodiments of the present document and the features in the embodiments may be mutually and freely combined under the situation of no conflict.

### Embodiment 1

A fall-proof method using a terminal device accessory provided by the embodiment of the present document is used for a terminal device accessory having the following features that: the terminal device accessory includes: an accessory body, a control module at one end of the accessory body, a popup component on the accessory body and an accessory exposed part at the other end of the accessory body and arranged to be fit with a side surface of a terminal device when the accessory body is inserted into an earphone jack, herein the accessory exposed part is capable of being unfolded in an umbrella shape.

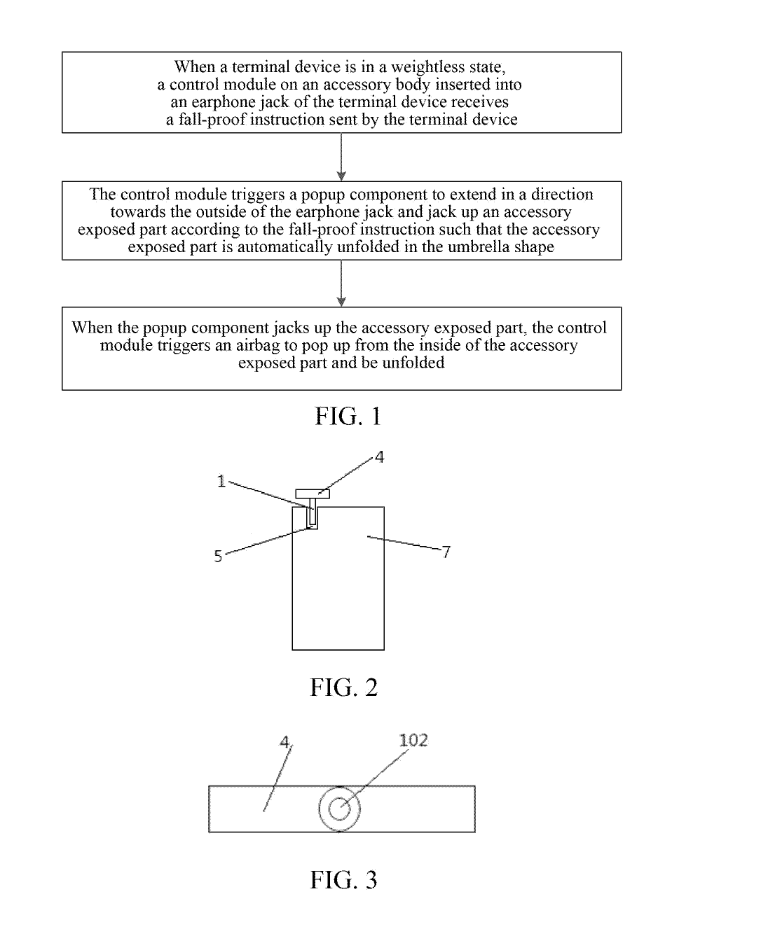

As illustrated in FIG. 1 which illustrates a flowchart of a fall-proof method using a terminal device accessory in the embodiment of the present document, the method includes the following steps:

In step S11, when the terminal device is in a weightless state, the control module on the accessory body inserted into the earphone jack of the terminal device receives a fall-proof instruction sent by the terminal device.

In the embodiment of the present document, the terminal device may be a terminal device with an earphone jack such as a smart phone, a tablet computer, a portable game machine or a music play terminal, and the terminal device accessory may be a dustproof plug or a smart key. Of course, it can be understood that the specific structure of the terminal device accessory is not limited in the embodiment of the present document.

In step S13, the control module triggers the popup component to extend in a direction towards the outside of the earphone jack and jack up the accessory exposed part according to the fall-proof instruction such that the accessory exposed part is automatically unfolded in the umbrella shape.

In the embodiment of the present document, the state of the terminal device may be comprehensively judged according to various factors such as gravity, terrestrial magnetism or light sensors. When the terminal device is in a weightless state, the terminal device sends a fall-proof instruction to the terminal device accessory to trigger the popup component in the terminal device accessory to extend towards the outside of the earphone jack along the axial direction of the accessory body and jack up the accessory exposed part (for example, the jacked-up accessory exposed part is certain distance higher than the edge of the terminal device), so as to prevent the appearance and even internal functions of the terminal device from being damaged.

In addition, when the accessory exposed part is jacked up by the popup component, the accessory exposed part is automatically unfolded, at this moment the top of the accessory exposed part protrudes, the edge faces to the terminal device and the accessory exposed part is in the umbrella shape. By unfolding the accessory exposed part, the air resistance can be effectively increased when the terminal device falls down and an effect similar to a parachute is achieved. Of course, it can be understood that the shape of the unfolded accessory exposed part is not limited in the embodiment of the present document.

Alternatively, in step S11, the control module on the accessory body inserted into the earphone jack of the terminal device receiving the fall-proof instruction sent by the terminal device includes:

the control module on the accessory body inserted into the earphone jack of the terminal device receiving the fall-proof instruction sent by the terminal device through a left sound channel contact end, a right sound channel contact end or a microphone contact end of the earphone jack.

In other words, in the embodiment of the present document, the terminal device accessory may receive the fall-proof instruction sent by the terminal device by using the left sound channel contact end, the right sound channel contact end of the earphone jack or the microphone contact end in the earphone jack. Specifically, in the embodiment of the present document, the structure of the front end of the accessory body may be similar to the structure of front-end four sections of an earphone, the control module may freely select a corresponding section of a left sound channel, aright sound channel or a microphone as a channel for receiving the fall-proof instruction from the terminal device, herein a ground wire is reserved. Except the section for receiving the fall-proof instruction and the section corresponding to the ground wire, the other two sections are reserved as optional, the instruction from the terminal device is received according to different positions and the received instruction of the control module in a columnar body can be extended.

Alternatively, the terminal device accessory further includes: an airbag in the accessory exposed part, and correspondingly, after step S13, the fall-proof method using the terminal device accessory further includes the following step:

In step S15, when the popup component jacks up the accessory exposed part, the control module triggers the airbag to pop up from the inside of the accessory exposed part and be unfolded.

In the embodiment of the present document, the falling speed of the terminal device can be reduced through the airbag which pops up and is unfolded, and the falling terminal device is protected through the unfolded airbag, such that the terminal device can safely fall down to the ground without being damaged regardless of the direction from which the terminal device falls down.

Herein, if the earphone jack faces to the direction of sky when the terminal device falls down, the airbag which pops up can also achieve the effect of reducing speed; if the earphone jack faces to the ground when the terminal device falls down, the airbag can further prevent the terminal device from directly contacting the ground to achieve an effect similar to an air cushion; and if other side surfaces of the terminal device face to the ground when the terminal device falls down, the airbag contacts the ground prior to the terminal device due to the large volume of the airbag, thus the impact force when the terminal device falls down is reduced and the terminal device is prevented from being damaged.

### Embodiment 2

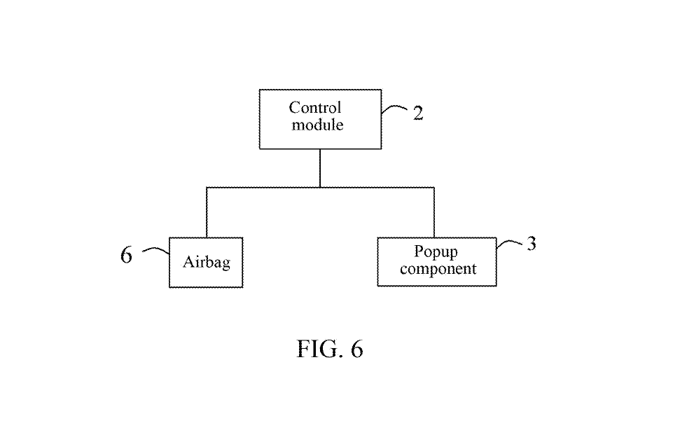

According to another embodiment of the present document, a terminal device accessory for being inserted into an earphone jack 5 of a terminal device 7 is further provided. As illustrated in FIGS. 2-6, the terminal device accessory includes:

an accessory body 1;

a control module 2 at one end of the accessory body 1, arranged to, when the terminal device 7 is in a weightless state, receive a fall-proof instruction sent by the terminal device 7 and generate and output a trigger signal according to the fall-proof instruction;

an accessory exposed part 4 at the other end of the accessory body 1, arranged to be fit with a side surface of the terminal device 7 when the accessory body 1 is inserted into the earphone jack 5, the accessory exposed part 4 being capable of being unfolded in an umbrella shape; and

a popup component 3 on the accessory body 1, arranged to extend towards the outside of the earphone jack 5 and jack up the accessory exposed part 4 according to the trigger signal output by the control module 2 such that the accessory exposed part 4 is automatically unfolded in the umbrella shape, a signal input end of the popup component 3 being connected with a signal output end of the control module 2.

In the embodiment of the present document, the shape of the accessory exposed part 4 is changeable. By inserting the terminal device accessory into the earphone jack 5 of the terminal device 7, not only can an effect of a dustproof plug be achieved under a general situation, but also the terminal device 7 can be prevented from being damaged when the terminal device 7 falls down.

In addition, when the popup component 3 jacks up the accessory exposed part 4, the accessory exposed part 4 is automatically unfolded in the umbrella shape, such that the accessory exposed part 4 achieves an effect similar to a parachute when the terminal device 7 falls down.

Alternatively, the control module 2 includes: a control circuit, a signal input end connected with the control circuit and a signal output end connected with the control circuit, herein the signal input end is connected with a left sound channel contact end, a right sound channel contact end or a microphone contact end in the earphone jack 5.

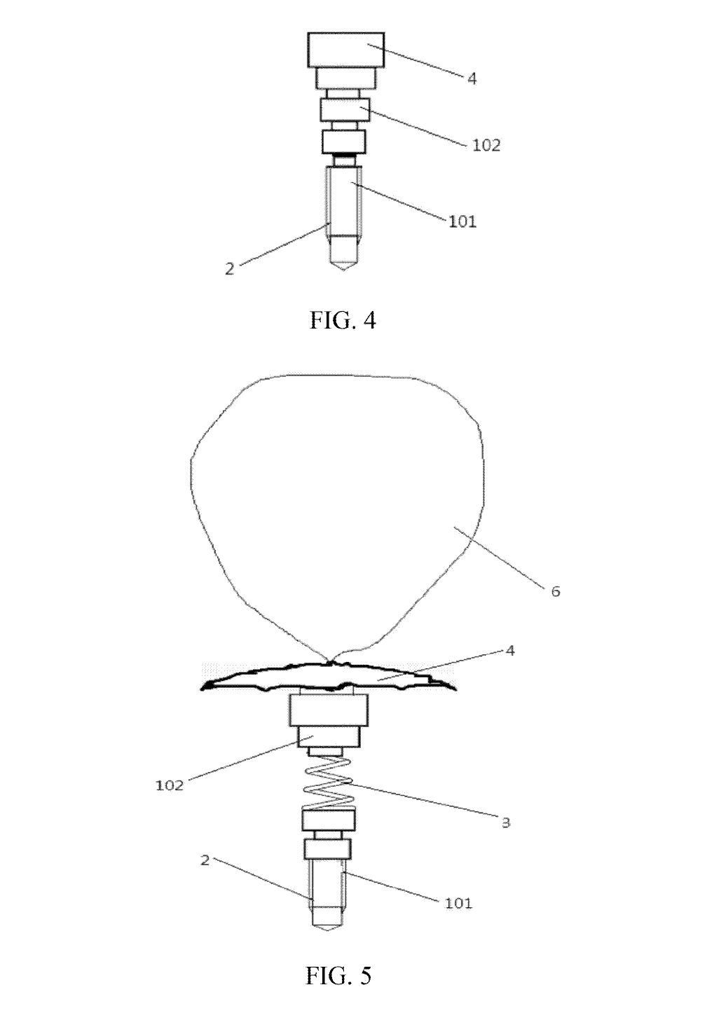

Alternatively, as illustrated in FIG. 4 and FIG. 5, the accessory body 1 includes: a first columnar body 101 and a second columnar body 102, one end of the first columnar body 101 is connected with one end of the popup component 3, the other end of the popup component 3 is connected with one end of the second columnar body 102 and the other end of the second columnar body 102 is connected with the accessory exposed part 4, herein the control module 2 is located on the first columnar body 101.

Herein, the popup component 3 is in a compressed state when the terminal device 7 does not fall down and pops up and is in an extended state when the terminal device 7 falls down. Besides, after the popup component 3 pops up, the popup component 3 may be manually restored to an original state. In addition, when the terminal device 7 falls down and the earphone jack 5 faces to the ground, the popup component 3 can reduce the falling speed of the terminal device 7 and thus protect the terminal device 7.

Alternatively, the other end of the second columnar body 102 is connected with the accessory exposed part 4 in a fixed or rotatable manner. Therefore, when the terminal device 7 falls down, the rotatable fixed part may produce upward lifting force due to factors such as air flow and thus a fall-proof effect is achieved.

Alternatively, as illustrated in FIG. 5, the terminal device accessory further includes: an airbag in the accessory exposed part 4, which is used to, when the popup component 3 jacks up the accessory exposed part 4, pop up from the inside of the accessory exposed part 4. As illustrated in FIG. 3, the airbag 6 may pop up from a center circle part of the accessory exposed part 4. If the earphone jack 5 faces to the ground when the terminal device 7 falls down, the airbag 6 which pops up can increase the falling resistance of the terminal device 7; and if other side surfaces of the terminal device 7 face to the ground when the terminal device 7 falls down, the airbag 6 which pops up can firstly touch the ground to change the falling direction and relieve the impact force, and thus the terminal device 7 is prevented from being damaged.

Alternatively, the other end of the second columnar body 102 is connected with the accessory exposed part 4 in a fixed or rotatable manner.

### Embodiment 3

According to another embodiment of the present document, a terminal device accessory is further provided, which includes:

an accessory exposed part 4, the accessory exposed part 4 being capable of being unfolded in an umbrella shape; and

an insertion part connected with the accessory exposed part 4 and arranged to be fixed in an earphone jack 5 of a terminal device 7, a popup component 3 being arranged on the insertion part, the popup component 3 being capable of jacking up the accessory exposed part 4 such that the accessory exposed part 4 is automatically unfolded in the umbrella shape.

Regardless of the direction which faces to the ground when the terminal device 7 falls down, the terminal device accessory can prevent the terminal device 7 from being damaged.

Alternatively, the insertion part includes: a first columnar body 101 and a second columnar body 102, one end of the first columnar body 101 is connected with one end of the popup component 3, the other end of the popup component 3 is connected with one end of the second columnar body 102 and the other end of the second columnar body 102 is connected with the accessory exposed part 4.

Alternatively, the other end of the second columnar body 102 is connected with the accessory exposed part 4 in a fixed or rotatable manner. Therefore, when the terminal device 7 falls down, the rotatable fixed part may produce upward lifting force due to factors such as air flow and thus the falling speed of the terminal device 7 is reduced.

Alternatively, the terminal device accessory further includes: an airbag 6 in the accessory exposed part 4, and the airbag 6 is automatically unfolded when the accessory exposed part 4 is jacked up. The unfolded airbag 6 not only can achieve an effect similar to an air cushion, but also can further reduce the falling speed of the terminal device 7.

Alternatively, the other end of the second columnar body 102 is connected with the accessory exposed part 4 in a fixed or rotatable manner.

In the terminal device accessory provided by the embodiment of the present document, there are optional combination modes for the popup component 3, the accessory exposed part 4, the airbag 6 and the connection mode of the second columnar body 102 and the accessory exposed part, as shown in Table 1.

TABLE 1
Terminal device accessory combination mode

| | | | | Connection |
|---|---|---|---|---|
| | | | | mode of second |
| | | | | columnar body |
| | | Accessory | | and accessory |
| | Popup | exposed | | exposed part |
| | component | part | Airbag | (fixed or |
| | (required) | (required) | (optional) | rotatable) |
| Combination | ✓ | ✓ | ✓ | Fixed |
| mode 1 | | | | |
| Combination | ✓ | ✓ | ✓ | Rotatable |
| mode 2 | | | | |
| Combination | ✓ | ✓ | X | Fixed |
| mode 3 | | | | |
| Combination | ✓ | ✓ | X | Rotatable |
| mode 4 | | | | |

Herein, the popup component 3 and the accessory exposed part 4 are indispensable parts of the terminal device accessory provided by the embodiment of the present document, the airbag 6 is optional, and the connection modes of the second columnar body 102 and the accessory exposed part 4 include two connection modes, i.e., fixed connection and rotatable connection.

### Embodiment 4

According to another embodiment of the present document, a terminal device is further provided, including: a terminal device accessory, the terminal device accessory including:

an accessory body 1;

a control module 2 at one end of the accessory body 1, arranged to, when the terminal device 7 is in a weightless state, receive a fall-proof instruction sent by a weightless state detection module and generate and output a trigger signal according to the fall-proof instruction;

an accessory exposed part 4 at the other end of the accessory body 1, arranged to be fit with a side surface of the terminal device 7 when the accessory body 1 is inserted into an earphone jack 5, the accessory exposed part 4 being capable of being unfolded in an umbrella shape; and

a popup component 3 on the accessory body 1, arranged to extend in a direction towards the outside of the earphone jack 5 and jack up the accessory exposed part 4 according to the trigger signal output by the control module 2 such that the accessory exposed part 4 is automatically unfolded in the umbrella shape, a signal input end of the popup component 3 being connected with a signal output end of the control module 2.

### Embodiment 5

According to another embodiment of the present document, a terminal device is further provided, including a terminal device accessory, the terminal device accessory including:

an accessory exposed part 4, the accessory exposed part 4 being capable of being unfolded in an umbrella shape; and

an insertion part connected with the accessory exposed part 4 and arranged to be fixed in an earphone jack 5 of a terminal device 7, a popup component 3 being arranged on the insertion part, the popup component 3 being capable of jacking up the accessory exposed part 4 such that the accessory exposed part 4 is automatically unfolded in the umbrella shape.

The above-mentioned embodiments are preferred embodiments of the present document. It should be pointed out that one skilled in the art may make multiple improvements and modifications without departing from the principle of the present document. However, such improvements and modifications are also included in the protection scope of the present document.

### INDUSTRIAL APPLICABILITY

The embodiments of the present document can reduce the impact force when the terminal device falls down and prevent the terminal device from being damaged.

What is claimed is:

1. A fall-proof method using a terminal device accessory, comprising,
the terminal device accessory comprising: an accessory body, a control module at one end of the accessory body, a popup component on the accessory body and an accessory exposed part at the other end of the accessory body and arranged to be fit with a side surface of the terminal device when the accessory body is inserted into an earphone jack, the accessory exposed part being capable of being unfolded in an umbrella shape,
when the terminal device is in a weightless state, the control module on the accessory body inserted into the earphone jack of the terminal device receiving a fall-proof instruction sent by the terminal device; and
the control module triggering the popup component to extend in a direction towards outside of the earphone jack and jack up the accessory exposed part according to the fall-proof instruction such that the accessory exposed part is automatically unfolded in the umbrella shape.

2. The method according to claim 1, wherein the control module on the accessory body inserted into the earphone jack of the terminal device receiving the fall-proof instruction sent by the terminal device comprises:
the control module receiving the fall-proof instruction sent by the terminal device through a left sound channel contact end, a right sound channel contact end or a microphone contact end of the earphone jack of the terminal device.

3. The method according to claim 1, wherein the terminal device accessory further comprises: an airbag inside the accessory exposed part, and the method further comprises:
when the popup component jacks up the accessory exposed part, the control module triggering the airbag to pop up from inside of the accessory exposed part and be unfolded.

4. A terminal device accessory for being inserted into an earphone jack of a terminal device, comprising:
an accessory body;
a control module at one end of the accessory body, arranged to, when the terminal device is in a weightless state, receive a fall-proof instruction sent by the terminal, generate and output a trigger signal according to the fall-proof instruction;
an accessory exposed part at the other end of the accessory body, arranged to be fit with a side surface of the terminal device when the accessory body is inserted into the earphone jack, the accessory exposed part being capable of being unfolded in an umbrella shape; and
a popup component on the accessory body, arranged to extend in a direction towards outside of the earphone jack and jack up the accessory exposed part according to the trigger signal output by the control module such that the accessory exposed part is automatically unfolded in the umbrella shape, a signal input end of the popup component being connected with a signal output end of the control module.

5. The terminal device accessory according to claim 4, wherein the control module comprises: a control circuit, a signal input end connected with the control circuit and a signal output end connected with the control circuit, wherein the signal input end is arranged to be connected with a left sound channel contact end, a right sound channel contact end or a microphone contact end in the earphone jack.

6. The terminal device accessory according to claim 5, wherein the accessory body comprises: a first columnar body and a second columnar body, one end of the first columnar body is connected with one end of the popup component, the other end of the popup component is connected with one end of the second columnar body and the other end of the second columnar body is connected with the accessory exposed part, wherein the control module is located on the first columnar body.

7. The terminal device accessory according to claim 6, wherein the other end of the second columnar body is connected with the accessory exposed part in a fixed or rotatable manner.

8. The terminal device accessory according to claim 6, the terminal device accessory further comprising: an airbag inside the accessory exposed part, which is arranged to, when the popup component jacks up the accessory exposed part, pop up from inside of the accessory exposed part and be unfolded according to a trigger of the control module.

9. The terminal device accessory according to claim 8, wherein the other end of the second columnar body is connected with the accessory exposed part in a fixed or rotatable manner.

10. A terminal device accessory, comprising:
an accessory exposed part, the accessory exposed part being capable of being unfolded in an umbrella shape; and
an insertion part connected with the accessory exposed part and arranged to be fixed in an earphone jack of a terminal device, a popup component being arranged on the insertion part, the popup component being capable of jacking up the accessory exposed part such that the accessory exposed part is automatically unfolded in the umbrella shape.

11. The terminal device accessory according to claim 10, wherein the insertion part comprises: a first columnar body and a second columnar body, one end of the first columnar body is connected with one end of the popup component, the other end of the popup component is connected with one end of the second columnar body and the other end of the second columnar body is connected with the accessory exposed part.

12. The terminal device accessory according to claim 11, wherein the other end of the second columnar body is connected with the accessory exposed part in a fixed or rotatable manner.

13. The terminal device accessory according to claim 11, the terminal device accessory further comprising: an airbag inside the accessory exposed part, and the airbag is automatically unfolded when the accessory exposed part is jacked up.

14. The terminal device accessory according to claim 13, wherein the other end of the second columnar body is connected with the accessory exposed part in a fixed or rotatable manner.

15. A terminal device, comprising: the terminal device accessory according to claim 4.

16. A terminal device, comprising: the terminal device accessory according to claim 10.

17. A terminal device, comprising: the terminal device accessory according to claim 5.

18. A terminal device, comprising: the terminal device accessory according to claim 11.

19. A terminal device, comprising: the terminal device accessory according to claim 6.

20. A terminal device, comprising: the terminal device accessory according to claim 12.
